(19) United States
(12) Patent Application Publication
(10) Pub. No.: US 2016/0133707 A1
(43) Pub. Date: May 12, 2016

(54) SILICON CARBIDE SEMICONDUCTOR DEVICE AND METHOD FOR MANUFACTURING SAME

(71) Applicant: SUMITOMO ELECTRIC INDUSTRIES, LTD., Osaka (JP)

(72) Inventors: Ryosuke KUBOTA, Osaka-shi (JP); Takeyoshi MASUDA, Osaka-shi (JP)

(21) Appl. No.: 14/899,310

(22) PCT Filed: May 9, 2014
(86) PCT No.: PCT/JP2014/062425

§ 371 Date: Dec. 17, 2015

(30) Foreign Application Priority Data
Jun. 19, 2013 (JP) 2013-128506

(51) Int. Cl. H01L 29/16; H01L 29/739; H01L 29/66; H01L 29/78; H01L 21/04; H01L 29/167

(52) U.S. Cl. CPC H01L 29/1608; H01L 21/0465; H01L 29/167; H01L 29/66068; H01L 29/7802; H01L 29/7395

(57) ABSTRACT

A method includes steps of: preparing a silicon carbide substrate having a first surface and including a first impurity region having a first conductivity type; forming an adjustment film and a mask film, the adjustment film covering at least a portion of the first surface, the mask film having an opening pattern through which the adjustment film is at least partially exposed; forming a second impurity region having a second conductivity type in the first impurity region by implanting an impurity into the first surface through the adjustment film using the mask film as a mask; and removing at least a portion of the adjustment film; and forming a third impurity region having the first conductivity type in the second impurity region by implanting an impurity into the first surface using the mask film as a mask.

### TECHNICAL FIELD

The present invention relates to a silicon carbide semiconductor device and a method for manufacturing the silicon carbide semiconductor device, in particular, a silicon carbide semiconductor device in which a channel length is controlled with high precision as well as a method for manufacturing such a silicon carbide semiconductor device.

### BACKGROUND ART

Silicon carbide (SiC) is a wide band gap semiconductor having a band gap larger than that of silicon (Si), which has been conventionally widely used as a material for semiconductor devices. Silicon carbide (SiC) has a large dielectric breakdown electric field. Moreover, SiC has larger electron saturation rate and thermal conductivity than those of Si and therefore has a characteristic excellent as a semiconductor material for power semiconductor devices.

By adopting silicon carbide as a material for a semiconductor device, the semiconductor device can have high breakdown voltage, reduced on resistance, and the like; however, development has been conducted to achieve higher breakdown voltage and higher speed. Moreover, development has also been conducted to achieve a finer semiconductor device.

Japanese Patent Laying-Open No. 10-233503 discloses a method for manufacturing a silicon carbide vertical type MOSFET, wherein phosphorus ions are selectively implanted using a mask having a large width, then boron ions are selectively implanted using a mask having a narrower width, then the mask having the narrower width is removed, and then heat treatment is performed to form a p base region and an n source region. Thus, it is described that by forming the p base region and the n source region through the ion implantations using the two different masks, the length (channel length) of a channel region and the thickness of the p base region can be designed independently, thus attaining a structure suitable for high breakdown voltage to avoid punch through in the channel region, for example.

### CITATION LIST

### Patent Document

PTD 1: Japanese Patent Laying-Open No. 10-233503

### SUMMARY OF INVENTION

### Technical Problem

However, in the method described in Japanese Patent Laying-Open No. 10-233503, the ion implantations are performed using the two different masks for the p base region and Chen source region, with the result that the length of the channel region is determined by a relative positional relation between the two masks. In other words, with the method described in the publication above, the channel lengths of silicon carbide semiconductor devices formed will include variations among batches or lots, which are caused in the following two steps: the step of forming the mask having the large width and used for the ion implantation for formation of the n source region; and the step of processing the mask having the large width into the mask having the narrower width. Accordingly, with the method described in the publication, it is difficult to form the channel length of the silicon carbide semiconductor device by controlling it in a submicron order, thus making it difficult to achieve a higher speed switching characteristic of a silicon carbide semiconductor device and realization of a liner silicon carbide semiconductor device.

The present invention is made to solve the above problem. The present invention has a main object to provide a silicon carbide semiconductor device having a channel length controlled in the submicron order as well as a method for manufacturing such a silicon carbide semiconductor device.

### Solution to Problem

A method for manufacturing a silicon carbide semiconductor device according to the present invention includes steps of preparing a silicon carbide substrate having a first surface and including a first impurity region having a first conductivity type; forming an adjustment film and a mask film, the adjustment film covering at least a portion of the first surface, the mask film having an opening pattern through which the adjustment film is at least partially exposed; thrilling a second impurity region having a second conductivity type in the first impurity region by implanting an impurity into the first surface through the adjustment film using the mask film as a mask; removing at least a portion of the adjustment film; and forming a third impurity region having the first conductivity type in the second impurity region by implanting an impurity into the first surface using the mask film as a mask after the step of removing at least the portion of the adjustment film.

### Advantageous Effects of Invention

According to the present invention, there can be obtained a silicon carbide semiconductor device having a channel length controlled in the submicron order.

### BRIEF DESCRIPTION OF DRAWINGS

FIG. 1 is a cross sectional view showing a configuration of a silicon carbide semiconductor device according to an embodiment of the present invention.

FIG. 2 is a flowchart of a method for manufacturing the silicon carbide semiconductor device according to the embodiment of the present invention.

FIG. 3 is a cross sectional view for illustrating the method for manufacturing the silicon carbide semiconductor device according to the embodiment of the present invention.

FIG. 4 is a cross sectional view for illustrating the method for manufacturing the silicon carbide semiconductor device according to the embodiment of the present invention.

FIG. 5 is a cross sectional view for illustrating the method for manufacturing the silicon carbide semiconductor device according to the embodiment of the present invention.

FIG. 6 is a cross sectional view for illustrating the method for manufacturing the silicon carbide semiconductor device according to the embodiment of the present invention.

FIG. 7 is a cross sectional view for illustrating the method for manufacturing the silicon carbide semiconductor device according to the embodiment of the present invention.

FIG. 8 is a cross sectional view for illustrating the method for manufacturing the silicon carbide semiconductor device according to the embodiment of the present invention.

FIG. 9 is a cross sectional view for illustrating a modification of the method for manufacturing the silicon carbide semiconductor device according to the embodiment of the present invention.

FIG. 10 is a cross sectional view for illustrating the modification of the method for manufacturing the silicon carbide semiconductor device according to the embodiment of the present invention.

FIG. 11 is a cross sectional view for illustrating the modification of the method for manufacturing the silicon carbide semiconductor device according to the embodiment of the present invention.

FIG. 12 is a graph showing a calculation result of an example of the present invention.

FIG. 13 is a graph showing a calculation result of the example of the present invention.

### DESCRIPTION OF EMBODIMENTS

The following describes an embodiment of the present invention with reference: to figures. It should he noted that in the below-mentioned figures, the same or corresponding portions are given the same reference characters and are not described repeatedly. Regarding crystallographic indications in the present specification, an individual orientation is represented by [], a group orientation is represented by <>, and an individual plane is represented by ( ), and a group plane is represented by {} In addition, a negative crystallographic index is normally expressed by putting “−” (bar) above a numeral, but is expressed by putting the negative sign before the numeral in the present specification.

First, the following describes an overview of embodiments of the present invention.

(1) A method for manufacturing a silicon carbide semiconductor device according to the present invention includes steps of: preparing (S10) a silicon carbide substrate 10 having a first surface (main surface 10a) and including a first impurity region (drift region 12) having a first conductivity type; forming (S20) an adjustment film 2 and a mask film 1, adjustment film 2 covering at least a portion of the first surface (main surface 10a), mask film 1 having an opening pattern through which adjustment film 2 is at least partially exposed; forming (S30) a second impurity region (p body region 13) having a second conductivity type in the first impurity region (drift region 12) by implanting an impurity into the first surface (main surface 10a) through adjustment film 2 using mask film 1 as a mask; and removing (S40) at least a portion of adjustment film 2. The method further includes a step (S50) of forming a third impurity region (n+ source region 14) having the first conductivity type in the second impurity region (p body region 13) by implanting an impurity into the first surface (main surface 10a) using mask film 1 as a mask after the step (S40) of removing at least the portion of adjustment film 2.

Accordingly, the impurities to be implanted in the step (S30) of forming the second impurity region (p body region 13) and the step (S50) of forming the third impurity region (n+ source region 14) pass through adjustment film 2, thereby forming the second impurity region (p body region 13) and the third impurity region. (n+ source region 14) in the first impurity region (drift region 12) at its region on which adjustment film 2 is thrilled at the first surface (main surface 10a). Furthermore, when the impurities reach adjustment film 2, the impurities are scattered by adjustment film 2. As a result, the impurities are also implanted in the first impurity region (drift region 12) on which mask film 1 is formed at the first surface (main surface 10a) so as to expand to regions away from opening end portion 3 of mask film 1 by distances L1, L2 in the first surface (main surface 10a). On this occasion, a distance in which an impurity is expanded below mask film 1 as a result of being scattered by adjustment film 2 differs depending on the film thickness of adjustment film 2 (and implantation energy). By the step (S40) of removing at least a portion of adjustment film 2, film thickness h2 of adjustment film 2 in the step (S50) is reduced or removed as compared with film thickness hi of adjustment film 2 in the step (S30). Accordingly, the impurity implanted into the first surface (main surface 10a) in the step (S50) is not affected by scattering provided by adjustment film 2 or is less affected by scattering as compared with the impurity implanted into the first surface in the step (S30). As a result, in the step (S50), the impurity is also implanted into the first surface (main surface 10a) to expand to a region away from opening end portion 3 of mask film 1 by distance L2, which is shorter than distance L1. Accordingly, the third impurity region (n+ source region 14) can be formed in the second impurity region (p body region 13), whereby width L3 of the second impurity region (p body region 13) between the first impurity region (drift region 12) and the third impurity region (n+ source region 14) in the first surface on this occasion can be controlled with high precision in accordance with film thicknesses h1, L2 of adjustment film 2 and the implantation energies in the step (S30) and the step (S50).

(2) In the method for manufacturing the silicon carbide semiconductor device according to the present embodiment, an implantation energy for the impurity in the step (S30) of forming the second impurity region (p body region 13) may be higher than an implantation energy for the impurity in the step (S50) of forming the third impurity region (n+ source region 14).

In this way, the impurities implanted into the first surface (main surface 10a) can travel a long distance in adjustment film 2 and silicon carbide substrate 10 Accordingly, the second impurity region (p body region 13) can be formed to be wider in the in-plane direction of the first surface (main surface 10a) and have a deeper depth from the first surface (main surface 10a) than the third impurity region (n+ source region 14). A difference can be made great between the implantation energy for the impurity in the step (S30) and the implantation energy for the impurity in the step (S50), but by making the difference small, width L3 of the second impurity region (p body region 13) between the first impurity region (drift region 12) and the third impurity region (n+ source region 14) in the first surface can be made small.

(3) In the method for manufacturing the silicon carbide semiconductor device according to the present embodiment, in the step (S40) of removing, a film thickness of adjustment film 2 may be decreased such that a portion of adjustment film 2 remains on the first surface (main surface 10a).

In this way, in the step (S50) of forming the third impurity region (n+ source region 14), the impurity is implanted into the first surface (main surface 10a) through adjustment film 2 having film thickness h2. Since film thickness h2 is thinner than film thickness hi of adjustment film 2 in the step (S30) of forming the second impurity region (p body region 13), when implanted into the first surface (main surface 10a) in the step (S50), the impurity is less scattered by adjustment film 2 to result in a smaller width in which it is expanded below mask film 1 than that of the impurity implanted in the step (S30). As a result, in the step (S50), the impurity can be implanted into the first surface (main surface 10a) to expand to a region away from opening end portion 3 of mask film 1 by distance L2, which is shorter than distance L1. A difference can be made great between the film thickness of adjustment film 2 in the step (S30) and the film thickness of adjustment film 2 in the step (S50), but by making the difference small, width L3 of the second impurity region (p body region 13) between the first impurity region (drill region 12) and the third impurity region (n+ source region 14) in the first surface can he made small.

(4) In the method for manufacturing the silicon carbide semiconductor device according to the present embodiment, in the step (S40) of removing, adjustment film 2 on the first surface (main surface 10a) may be removed to expose the first surface (main surface 10a) in the opening pattern of mask film 1.

In this way, in the step (S50) of forming the third impurity region (n+ source region 14), the impurity is implanted into the first surface (main surface 10a) directly without passing through adjustment film 2. Accordingly, the impurity implanted into the first surface (main surface 10a) in the step (S50) is not scattered by adjustment film 2, whereby the third impurity region (n+ source region 14) is formed to have a width comparable to the opening of mask film 1 in the first surface (main surface 10a). As a result, the third impurity region (n+ source region 14) is formed in the second impurity region (p body region 13) formed using adjustment film 2 having film thickness h2. In this case, adjustment film 2 can be formed to cover at least a portion of the first surface (main surface 10a) and film thickness hi of adjustment film 2 formed in the step (S20) of forming mask film 1 to partially expose adjustment film 2 can also be increased; however, by making film thickness h1 small, width L3 of the second impurity region (p body region 13) between the first impurity region (drift region 12) and the third impurity region (n+ source region 14) in the first surface can be made small.

(5) The method for manufacturing the silicon carbide semiconductor device according to the present embodiment may further include a step of forming an electrode to apply a voltage to a portion of the second impurity region (p body region 13) between the first impurity region (drift region 12) and the third impurity region (n+ source region 14).

In this way, the second impurity region (p body region 13) between the first impurity region (drift region 12) and the third impurity region (n+ source region 14) in the first surface serves as the channel region, and width L3 of the second impurity region (p body region 13) between the first impurity region (drift region 12) and the third impurity region (n+ source region 14) in the first surface serves as the channel length.

(6) In the method for manufacturing the silicon carbide semiconductor device according to the present embodiment, adjustment film 2 may be made of a material selected from a group consisting of polycrystalline silicon (polysilicon), titanium, and silicon dioxide.

Also in this way, the impurity to be implanted into the first surface (main surface 10a) can pass through and can be scattered by adjustment film 2 in each of the step (S30) of forming the second impurity region (p body region 13) and the step (S50) of forming the third impurity region (n+ source region. 14). Moreover, adjustment film 2 can be formed to cover at least a portion of the first surface (main surface 10a) and the film thickness of adjustment film 2 can be controlled with high precision in each of the step (S20) of forming mask film 1 to partially expose adjustment film 2 and the step (S40) of removing at least a portion of adjustment film 2.

(7) in the method for manufacturing the silicon carbide semiconductor device according to the present embodiment, in the step (S30) of forming the second impurity region (p body region 13), adjustment film 2 may have a thickness hi of not less than 0.05 μm and not more than 1.0 μm, and in the step (S50) of forming the third impurity region (n+ source region 14), adjustment film 2 may have a thickness h2 of not less than 0.00 μm and not more than 0.95 μm.

In this way, width L3 of the second impurity region (p body region 13) between the first impurity region (drift region 12) and the third impurity region (n+ source region 14) in the first surface can be not less than 0.05 μm and not more than 0.15 μm.

(8) In the method for manufacturing the silicon carbide semiconductor device according to the present embodiment, in the step (S30) of forming the second impurity region (p body region 13) and the step (S50) of forming the third impurity region (n+ source region 14), aluminum or boron may be implanted as a p type impurity and phosphorus may be implanted as an n type impurity. Also in this way, the impurity can be implanted into the first surface (main surface 10a) via adjustment film 2.

(9) In the method for manufacturing the silicon carbide semiconductor device according to the present embodiment, an implantation energy for the impurity in the step (S30) of forming the second impurity region (p body region 13) may be not less than 10 keV and not more than 1000 keV, and an implantation energy for the impurity in the step (S50) of forming the third impurity region (n+ source region 14) may be not less than 10 keV and not more than 500 keV.

In this way, the second impurity region (p body region 13) is formed to be wider than the third impurity region (n+ source region 14) in the in-plane direction (direction along the first surface) of the first surface (main surface 10a). Moreover, even when film thickness h1 of adjustment film 2 in the step (S30) of forming the second impurity region (p body region 13) is made thicker than film thickness h2 of adjustment film 2 in the step (S50) of forming the third impurity region (n+ source region 14), the second impurity region (p body region 13) can be formed to expand to a deeper position from the first surface (main surface 10a), whereby the third impurity region (n+ source region 14) is formed in the second impurity region (p body region 13).

(10) A silicon carbide semiconductor device 100 according to the present embodiment includes a silicon carbide substrate 10 having a first surface. Silicon carbide substrate 10 includes a first impurity region (drift region 12) formed in the first surface (main surface 10a) and having a first conductivity type, and a third impurity region (n+ source region 14) having the first conductivity type and facing the first impurity region (drift region 12) with a second impurity region (p body region 13) being interposed therebetween in the first surface (main surface 10a), the second impurity region (p body region 13) having a second conductivity type. The second impurity region (p body region 13) between the first impurity region (drift region 12) and the third impurity region (n+ source region 14) in the first surface (main surface 10a) has a width L3 of not less than 0.01 μm and not more than 0.15 μm.

In this way, width L3 of the second impurity region (p body region 13) between the first impurity region (drift region 12) and the third impurity region (n+ source region 14) in the first surface (main surface 10a) can serve as the channel length in silicon carbide semiconductor device 100. In other words, since the channel length of silicon carbide semiconductor device 100 is very short to be about not less than 0.01 μm and not more than 0.15 μm, silicon carbide semiconductor device 100 can attain a higher speed switching characteristic and can be finer.

The following describes an embodiment of the present invention in detail with reference to figures.

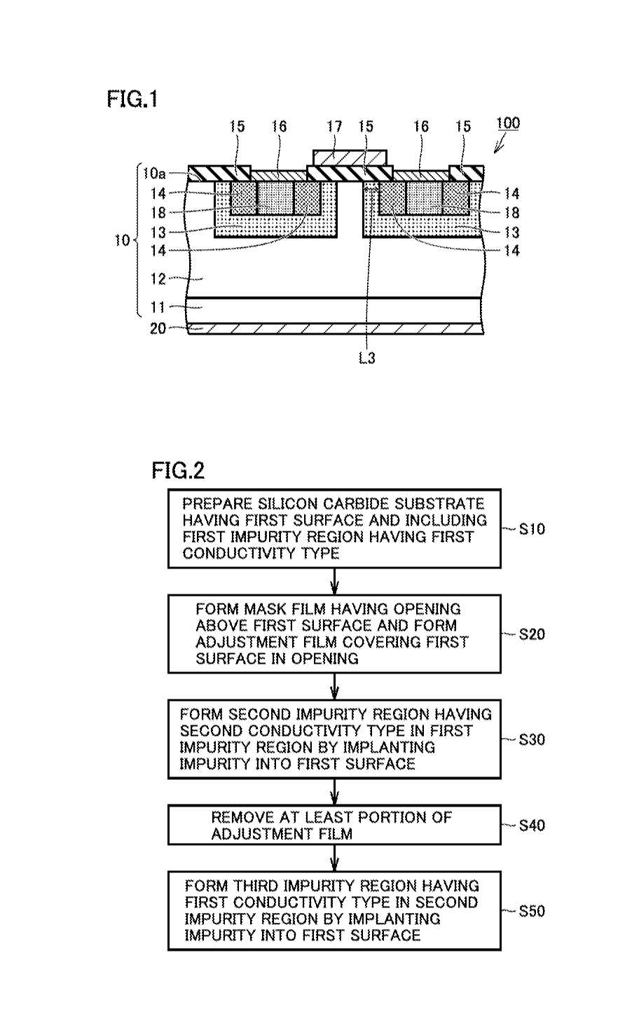

First, with reference to FIG. 1, the structure of a silicon carbide semiconductor device according to the present embodiment is illustrated. Silicon carbide semiconductor device 100 according to the present embodiment is configured as a MOSFET.

For example, silicon carbide semiconductor device 100 mainly includes a silicon carbide substrate 10 made of hexagonal silicon carbide, gate insulating films 15, gate electrodes 17, source electrodes 16, and a drain electrode 20. Silicon carbide substrate 10 mainly includes an n+ substrate 11, a drift region 12, p body regions 13, n+ source regions 14, and p+ regions 18. Silicon carbide substrate 10 is made of hexagonal silicon carbide, for example. Silicon carbide substrate 10 may have a main surface 10a corresponding to, for example, a plane angled off by not more than 8° relative to a {0001} plane.

N+ substrate 11 is a substrate having n type conductivity (first conductivity type). N+ substrate contains an n type impurity such as nitrogen (N) at a high concentration, for example. The concentration of the impurity such as nitrogen in n+ substrate 11 is about 1.0×10¹⁸ cm, for example.

Drift region 12 is an epitaxial layer having it type conductivity. Drift region 12 is formed on n+ substrate 11. Drift region 1:2 has a depth T1 of about 15 μm, for example. Preferably, depth T1 of drill region 12 is not less than 14.5 μm and not more than 15.5 μm. The n type impurity in drift region 12 is, for example, nitrogen and the n type impurity is contained therein at an impurity concentration lower than that of the n type impurity in n+ substrate 11. The concentration of the impurity such as nitrogen in drill region 12 is about 7.5×10¹⁵ cm⁻³, for example,

P body region 13 has p type conductivity. In drift region 12, p body region 13 is formed to include main surface 10a of silicon carbide substrate 10. The p type impurity in p body region 13 is aluminum (Al), boron (B), or the like, for example. The concentration of the impurity such as aluminum in p body region 13 is about 1×10¹⁷ cm⁻³, for example.

N+ source region 14 has n type conductivity, N+ source region 14 is formed to include main surface 10a and is formed in p body region 13 such that n+ source region 14 is surround by p body region 13. The n type impurity in n+ source region 14 is P (phosphorus) or the like, for example. The concentration of the impurity such as phosphorus in n+ source region 14 is higher than that of the n type impurity in drift region 12, such as about 1×10²⁰ cm³.

In main surface 10a, p body region 13 between drift region 12 and n+ source region 14 has a width L3 of not less than 0.01 μm and not more than 0.15 μm.

P+ region 18 has p type conductivity. P+ region 18 is formed in contact with main surface 10a and p body region 13 to extend through the vicinity of the center of n+ source region 14. P+ region 18 contains a p type impurity such as Al or B at a concentration higher than that of the p type impurity in p body region 13, for example, at a concentration of about 1×10²⁰ cm⁻³.

Gate insulating film 15 is formed in contact with drift region 12 to extend from above the upper surface of one n+ source region 14 to above the upper surface of the other n+ source region 14. Gate insulating film 15 is made of silicon dioxide (SiO₂), for example.

Gate electrode 17 is disposed on and in contact with gate insulating film 15 to extend from above one n+ source region 14 to above the other n+ source region 14. Gate electrode 17 is made of a conductor, such as polysilicon or Al.

In main surface 10a, source electrode 16 is disposed in contact with n+ source region 14 and p+ region 18. Source electrode 16 includes titanium (Ti) atoms, Al atoms, and silicon (Si) atoms, for example. Accordingly, source electrode 16 can make ohmic contact with each of the n type silicon carbide region (n+ source region 14) and the p type silicon carbide region (p+ region 18).

Drain electrode 20 is formed in contact with the main surface of n+ substrate 11 opposite to its main surface on which drift region 12 is formed. For example, this drain electrode 20 may have the same configuration as source electrode 16, or may be made of a different material capable of ohmic contact with n+ substrate 11 such as nickel (Ni). Accordingly, drain electrode 20 is electrically connected to n+ substrate 11.

Next, the following describes an operation of silicon carbide semiconductor device 100 according to the present embodiment. In the state in which gate electrode. 17 is fed with a voltage of not more than a threshold value, i.e., in the off state, the portion between p body region 13 and drift region 12 just below gate insulating film 15 is reverse-biased, thus resulting in the non-conductive state. On the other hand, when a positive voltage is applied to gate electrode 17, an inversion layer is formed in p body region 13 at its portion in contact with gate insulating film 15. As a result, n+ source region 14 and drift region 12 are electrically connected to each other with this inversion layer serving as a channel, with the result that a current flows between source electrode 16 and drain electrode 20. On this occasion, width L3 of p body region 13 between drift region 12 and n+ source region 14 in main surface 10a corresponds to the channel length of silicon carbide semiconductor device 100.

Next, with reference to FIG. 1 to FIG. 8, the following describes a method for manufacturing the silicon carbide semiconductor device according to the present embodiment.

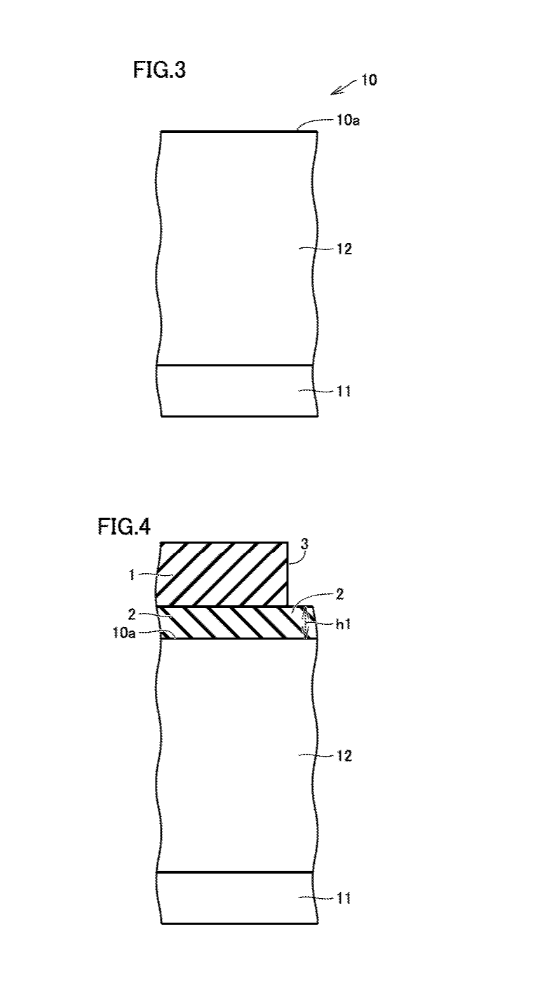

First, with reference to FIG. 3, silicon carbide substrate 10 is prepared which has main surface 10a and includes drift region 12 having n type conductivity (step (S10)). Specifically, drift region 12 is formed by means of epitaxial growth on one main surface of n+ substrate 11 made of hexagonal silicon carbide. The epitaxial growth can be performed using a mixed gas of silane (SiH₄) and propane (C₃H₈) as a source material gas, for example. On this occasion, nitrogen (N) is introduced as an n type impurity, for example. Accordingly, drift region 12 containing the n type impurity at a concentration lower than that of the n type impurity in film substrate 11 is formed on substrate 11.

Next, with reference to FIG. 4, an adjustment film 2 is formed to cover the whole of main surface 10a (step (S20)). Adjustment film 2 serves to allow an impurity to pass therethrough and be scattered during implantation into main surface 10a in a step (S30) of forming p body region 13. The material and film thickness h1 of adjustment film 2 are appropriately determined in accordance with transmission property and scattering probability of the impurity as required in the step (S30) of forming p body region 13. For example, adjustment film 2 may be made of polysilicon, which is formed by a CVD (Chemical Vapor Deposition) method. Film thickness h1 of adjustment film 2 is preferably not less than 0.05 μm and not more than 1.0 μm, and may be 0.2 μm, for example.

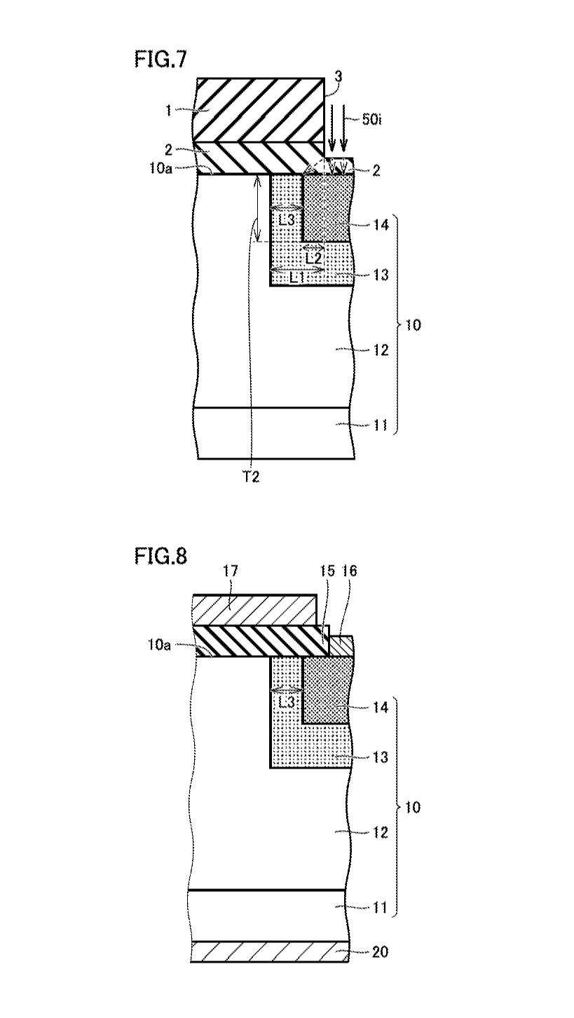

Furthermore, in this step (S20), a mask film 1 is formed to partially expose adjustment film 2. Mask film 1 is made of for example, a silicon oxide film such as silicon oxide (SiO₂), which is formed by the CVD (Chemical Vapor Deposition). Mask film 1 is provided with an opening shorter by a predetermined distance than each of a region to be provided with p body region 13 and a region to be provided with n+ source region 14 in main surface 10a. Specifically, for example, as shown in FIG. 5, mask film 1 is formed to have the opening with its opening end portion 3 located to correspond to an inner side of p body region 13 to be separated by a distance L1 from one side of the outer circumferential end portion of the region to be provided with p body region 13 in main surface 10a. Further, mask film 1 is formed with opening end portion 3 located to correspond to an inner side of n+ source region 14 to be separated by a distance L2 (see FIG. 7) from one side of the outer circumferential end portion of the region to be provided with n+ source region 14 in main surface 10a.

Next, with reference to FIG. 5, p body region 13 is formed (step (S30)). Specifically, using, as a mask, mask film 1 formed in the previous step (S20), a p type impurity is implanted into main surface 10a through adjustment film 2 having film thickness h1. The p type impurity is Al, B or the like, for example. Accordingly, p body region 13 having p type conductivity type is formed in drill region 12. On this occasion, the p type impurity is implanted at an implantation energy of 250 keV in an implantation direction 30i substantially perpendicular to main surface 10a, for example. P body region 13 is formed to expand below mask film 1 to an inner position relative to opening end portion 3 by distance L1 as a result of scattering of the impurity at the upper end of adjustment film 2 or the like. Moreover, p body region 13 is formed to extend to the position of a depth T1 from main surface 10a.

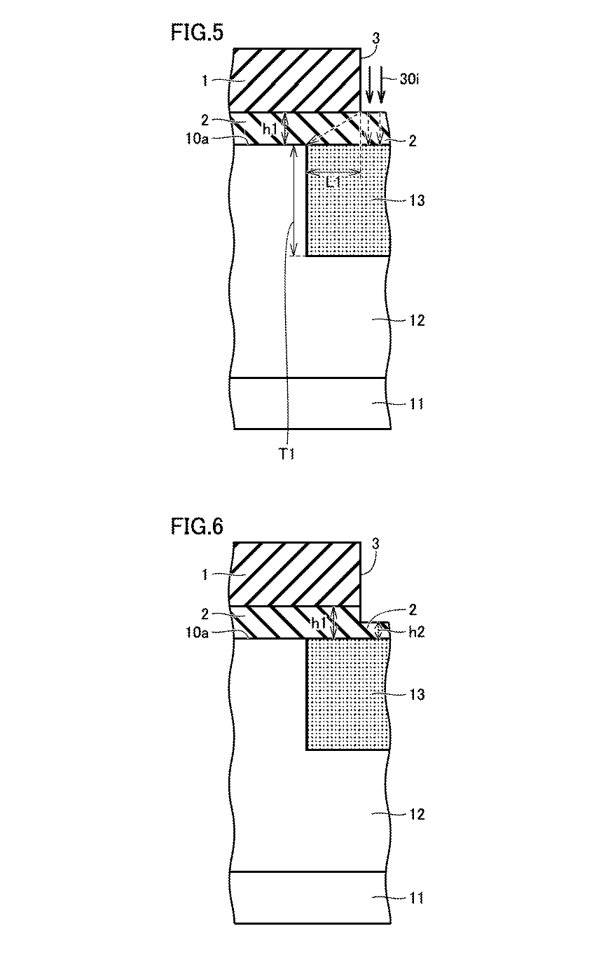

Next, with reference to FIG. 6, at least a portion of adjustment film 2 is removed (step (S40)). Specifically, film thickness hi of adjustment film 2 is reduced to a film thickness h2 such that a portion of adjustment film 2 remains on main surface 10a. For example, film thickness hi of adjustment film 2 may be reduced to film thickness h2 by any method, such as RIE (Reactive Ion Etching), that provides a large etching selectivity for adjustment film 2 with respect to mask film 1 (mask film 1 is not substantially etched) and that provides small in-plane variation in main surface 10a of silicon carbide substrate 10. Thus, this step (S40) does not substantially change the opening area of mask film 1. Film thickness h2 of adjustment film 2 is determined appropriately in accordance with the transmission property and scattering probability of the impurity as required in the step (S50) of forming n+ source region 14. Film thickness h2 of adjustment film 2 is preferably not more than 0.95 μm, and may be 0.15 μm, for example.

Next, with reference to FIG. 7, n+ source region 14 is formed (step (S50)) Specifically, mask film 1 is used as a mask to implant an n type impurity into main surface 10a through adjustment film 2 of film thickness h2 having been made thinner in the previous step (S40). The n type impurity P or the like, for example. Accordingly, n+ source region 14 having it type conductivity is formed in p body region 13. The implantation energy for the n type impurity on this occasion is lower than the implantation energy for the p type impurity in the previous step (S30), such as 50 keV. Implantation direction 50i of the n type impurity is parallel to implantation direction 30i of the p type impurity in the previous step (S30), and is substantially perpendicular to main surface 10a, for example. Film thickness h2 of adjustment film 2 in this step (S50) is thinner than film thickness h1 thereof in the previous step (S30). The impurity is scattered by the upper end of adjustment film 2 or the like, thereby forming n+ source region 14 expanding below mask film 1 to an inner position relative to opening end portion 3 by distance L2. Moreover, n+ source region 14 is formed to extend from main surface 10a to the position of a depth T2, Distance L2 is shorter than distance L1 in p body region 13, and depth T2 is shallower than depth T1 in p body region 13.

After forming n+ source region 14, mask film 1 and adjustment film 2 are removed. Any method may be employed to remove mask film 1 and adjustment film

Next, a mask layer having an opening at a region in conformity with the shape of desired p+ region 18 is formed. The mask layer is used as a mask to implant ions of a p type impurity such as Al or B into n+ source region 14, thereby forming p+ region 18.

Next, heat treatment is performed to activate the impurities implanted in silicon carbide substrate 10 (step (S60)). Specifically, silicon carbide substrate 10 is heated for about 30 minutes at about 1700° C. in an inert gas atmosphere, for example.

Next, gate insulating film 15 is formed (step (S70)). Specifically, silicon carbide substrate 10 is thermally oxidized as described above. The thermal oxidation is performed by, for example, heating silicon carbide substrate 10 at about 1300° C. in an oxygen atmosphere for about 40 minutes. Accordingly, gate insulating film 15 made of silicon dioxide is formed on main surface 10a of silicon carbide substrate 10.

Next, gate electrode 17 is formed (step (S80)). In this step, gate electrode 17 made of for example, a conductor such as polysilicon or Al is formed in contact with gate insulating film 15 so as to extend from above one n+ source region 14 to above the other n+ source region 14. In the case where polysilicon is employed as the material of gate electrode 17, the polysilicon may be configured to contain P at a high concentration of more than 1×10²⁰ cm⁻³. Then, an insulating film made of SiO₂ may be formed to cover gate electrode 17, for example.

Next, the ohmic electrode is formed (step (S90)). Specifically, for example, a resist pattern having an opening pattern above p+ region 18 and a portion of n+ source region 14 is formed. Etching is performed using the resist pattern as a mask, thereby partially removing gate insulating film 15 and the like. As a result, p+ region 18 and a portion of n+ source region 14 are exposed. Then, a metal film containing, for example, Si atoms, Ti atoms, and Al atoms is formed on the entire surface of the substrate. The ohmic electrode is formed by a sputtering method or an evaporation method, for example. Then, for example, by lifting off the resist pattern, a metal film is formed in contact with gate insulating film 15, p+ region 18, and n+ source region 14. Then, for example, by heating the metal film at about 1000° C., source electrode 16 is formed in ohmic contact with silicon carbide substrate 10. Moreover, drain electrode 20 is formed in ohmic contact with n+ substrate 11 of silicon carbide substrate 10 in this way, silicon carbide semiconductor device 100 serving as a MOSFET as shown in FIG. 1 and FIG. 8 is completed.

Next, the following describes function and effect of the method for manufacturing the silicon carbide semiconductor device according to the present embodiment.

In the step (S30) of forming p body region 13 and the step (S50) of forming n+ source region 14, the impurities to be implanted in main surface 10a are scattered by adjustment film 2 as described above. The impurities scattered by adjustment film 2 travel in adjustment film 2 in a direction different from the implantation direction, and are therefore implanted into main surface 10a also at its region covered with mask film That is, p body region 13 and n+ source region 14 are expanded relative to the opening of mask film 1 in main surface 10a.

On this occasion, the widths of p body region 13 and n+ source region 14 in silicon carbide semiconductor device 100 according to the present embodiment in the in-plane direction of main surface 10a are determined in accordance with the opening area of mask film 1 formed in the step (S20), the material and film thicknesses h1, h2 of adjustment film 2, and the implantation energies for the impurities in the step (S30) and the step (S50). In other words, in the in-plane direction of main surface 10a, the expansions of p body region 13 and of source region 14 relative to the opening region of mask film 1 are determined in accordance with the material and film thicknesses h1, h2 of adjustment film 2 and the implantation energies for the impurities in the step (S30) and the step (S50).

When adjustment film 2 is made of a material having a high scattering probability (scattering cross sectional area) with respect to an impurity to be implanted, the impurity to be implanted into main surface 10a is scattered by adjustment film 2 at a high probability. Hence, the expansion widths of p body region 13 and n+ source region 14 in main surface 10a become larger than those in the case where adjustment film 2 is made of a material having a low scattering probability. On the other hand, when adjustment film 2 is made of a material having a high scattering probability (scattering cross sectional area) with respect to an impurity to be implanted, depths T1, T2 of p body region 13 and n+ source region 14 from main surface 10a become shallower than those in the case where adjustment film 2 is made of a material having a low scattering probability.

An impurity having passed through adjustment film 2 comes into the region below mask film 1 by a distance that is in the in-plane direction of main surface 10a and that changes depending on the film thickness of adjustment film 2. Although the material of adjustment film 2 is the same in the step (S30) of forming p body region 13 and the step (S50) of forming n+ source region 14, film thickness h1 of adjustment film 2 in the step (S30) is thicker than film thickness h2 of adjustment film 2 in the step (S50). Accordingly, p body region 13 is formed to expand to the region covered with mask film 1 in the plane of main surface 10a by distance L1 from opening end portion 3 of mask film 1. On the other hand, n+ source region 14 is formed to expand to the region covered with mask film 1 in the plane of main surface 10a by distance 12 from opening end portion 3 of mask film 1. On this occasion, distance L1 is longer than distance L2.

Furthermore, on this occasion, in the step (S30) of forming p body region 13 and the step (S50) of forming n+ source region 14, opening end portion 3 of mask film 1 is in the same position relative to main surface 10a, and implantation direction 30i of the p type impurity and implantation direction 50i of the n type impurity are parallel to each other. Accordingly, by controlling film thickness hi of adjustment film 2 in the step (S30) and film thickness h2 of adjustment film 2 in the step (S50), width L3 (channel length) of p body region 13 between drift region 12 and n+ source region 14 in main surface 10a can be controlled as a difference between distance L1 by which p body region 13 is expanded relative to opening end portion 3 of mask film 1 and distance L2 by which n+ source region 14 is expanded relative to opening end portion 3 of mask film 1. It should be noted that in the present embodiment, implantation direction 30i of the p type impurity and implantation direction 50i of the n type impurity are parallel to each other, but the present invention is not limited to this. As long as implantation direction 30i of the p type impurity and implantation direction 50i. of the n type impurity are controlled as a predetermined relation, width L3 can be controlled as a difference between distance L1 and distance L2 by controlling film thicknesses h1, h2 of adjustment film 2 as described above.

Moreover, when an implantation energy for an impurity is high, the impurity implanted into main surface 10a can travel a long distance in adjustment film 2 and silicon carbide substrate 10. Specifically, the impurity is scattered by adjustment film 2 and travels in adjustment film 2 and silicon carbide substrate 10 in a direction different from the implantation direction. On this occasion, the impurity having the high implantation energy is implanted into main surface 10a even though it is scattered by adjustment film 2 for a multiplicity of times. Accordingly, when the implantation energy for the impurity is high, distances L1, L2 by which p body region 13 and n+ source region 14 are expanded can be made long relative to opening end portion 3 of mask film 1. Moreover, the implantation energy for the impurity in the step (S30) of forming p body region 13 is higher than the implantation energy for the impurity in the step (S50) of forming source region 14. Hence, the width of p body region 13 in the in-plane direction of main surface 10a is expanded more relative to the opening of mask film 1 as compared with the width of n+ source region 14 in the in-plane direction of main surface 10a.

As a result, by controlling film thicknesses h1, h2 of adjustment film 2 in a 0.05 μm order in the step (S20) and the step (S40) and controlling the implantation energies in a 1 keV order in the step (S30) and the step (S50), width L3 of p body region 13 between drift region 12 and n+ source region 1.4 in main surface 10a can be controlled in a submicron order. Accordingly, for example, width L3 can be not less than 0.01 μm and not more than 0.15 μm.

Moreover, the depths of p body region 13 and n+ source region 14 in silicon carbide semiconductor device 100 according to the present embodiment from main surface 10a are determined in accordance with the material and film thicknesses h1, h2 of adjustment film 2 formed in the step (S20) and the implantation energies for the impurities in the steps (S30) and (S50). As described above, by increasing the implantation energy for the impurity in the step (S30) to be higher than the implantation energy for the impurity in the step (S50), p body region 13 can be formed to extend from main surface 10a to a deeper position even when film thickness h1 of adjustment film 2 in the step (S30) is thicker than film thickness h2 of adjustment film 2 in the step (S50). Moreover, n+ source region 14 can be formed in p body region 13. As a result, p body region 13 is formed to have a wider width in the in-plane direction of main surface 10a and a deeper depth from main surface 10a than those of n+ source region 14.

As described above, in accordance with the silicon carbide semiconductor device and the method for manufacturing the silicon carbide semiconductor device according to the present embodiment, p body region 13 and n+ source region 14 are formed by implanting the impurities through different film thicknesses of adjustment film 2 while the same mask film 1 is used, whereby the widths of p body region 13 and n+ source region 14 in the in-plane direction of main surface 10a can be controlled by controlling the film thicknesses of adjustment film 2 and the implantation energies for the impurities. As a result, width 13 of p body region 13 between drift region 12 and of source region 14 in main surface 10a, i.e., the channel length of silicon carbide semiconductor device 100, can be controlled in the submicron order, thereby attaining a high-speed and finer silicon carbide semiconductor device 100.

The n type and p type conductivities of the impurity regions formed in silicon carbide semiconductor device 100 according to the present embodiment can be replaced with each other. Moreover, while the planar type MOSFET has been described as an exemplary silicon carbide semiconductor device in the present embodiment, the silicon carbide semiconductor device may be an IGBT (Insulated Gate Bipolar Transistor) or the like.

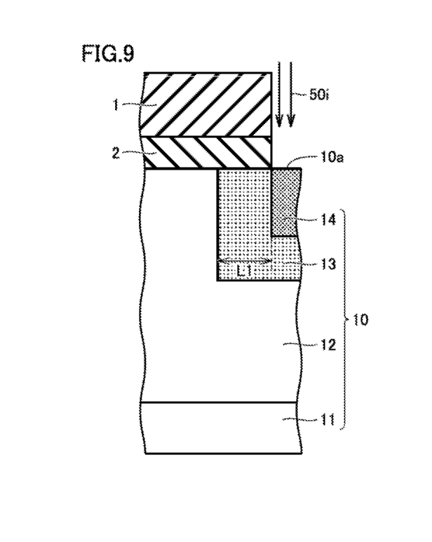

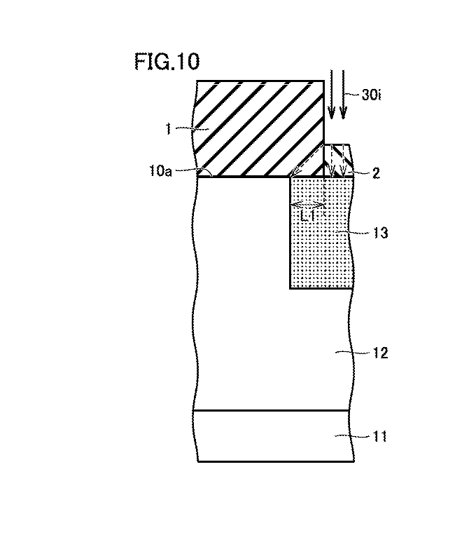

In the present embodiment, in the step (S40), the film thickness of adjustment film 2 is decreased such that a portion of adjustment film 2 remains on main surface 10a; however, the present invention is not limited to this. With reference to FIG. 9, adjustment film 2 may be completely removed in the step (S40), for example. In this way, the impurity to be implanted in the step (S50) is not scattered by adjustment film 2, with the result that distance L2 by which n+ source region 14 is expanded relative to opening end portion 3 of mask film 1 becomes small to such an extent that it can be ignored. Accordingly, in this case, distance L1 by which p body region 13 is expanded relative to opening end portion 3 of mask film 1 can be employed as width L3 of p body region 13 between drift region 12 and n+ source region 14 in main surface 10a, i.e., the channel length of silicon carbide semiconductor device 100, thus attaining the same effect as that in the present embodiment. In other words, in the step (S50), thickness 112 of adjustment film 2 may be not less than 0.00 μm and not more than 0.95 μm.

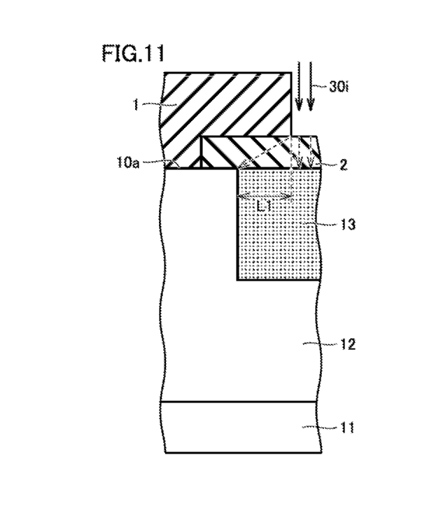

In the present embodiment, adjustment film 2 is formed to entirely cover main surface 10a, but the present invention is not limited to this. For example, with reference to FIG. 10, adjustment film 2 may be formed only in the opening of mask film 1. In this case, adjustment film 2 may be formed after forming mask film 1 on main surface 10a. Even in such a configuration, an impurity having reached and scattered by adjustment film 2 can pass through mask film 1 if it is a short distance, thus attaining the same effect as that of the present embodiment. Moreover, with reference to FIG. 11, for example, adjustment film 2 may be partially formed on main surface 10a (for example, on a portion of the region covered with mask film 1 in main surface 10a). Even in such a configuration, an impurity having reached and scattered by adjustment film 2 can pass through adjustment film 2, thus attaining the same effect as that of the present embodiment.

### EXAMPLE

In order to confirm the effect of the present invention, the following computer simulation was performed.

<Method to be Reviewed>

Regarding an impurity region formed when implanting an impurity into a main surface of a silicon carbide substrate covered with an adjustment film having a film thickness of 0.2 μm and made of polysilicon, expansion of the impurity region in the in-plane direction of the main surface and a depth of the impurity region from the main surface in the perpendicular direction were calculated with an implantation energy for the impurity being set at about not less than 10 eV and not more than 1000 eV. A Monte Carlo method was used for the calculation.

<Result>

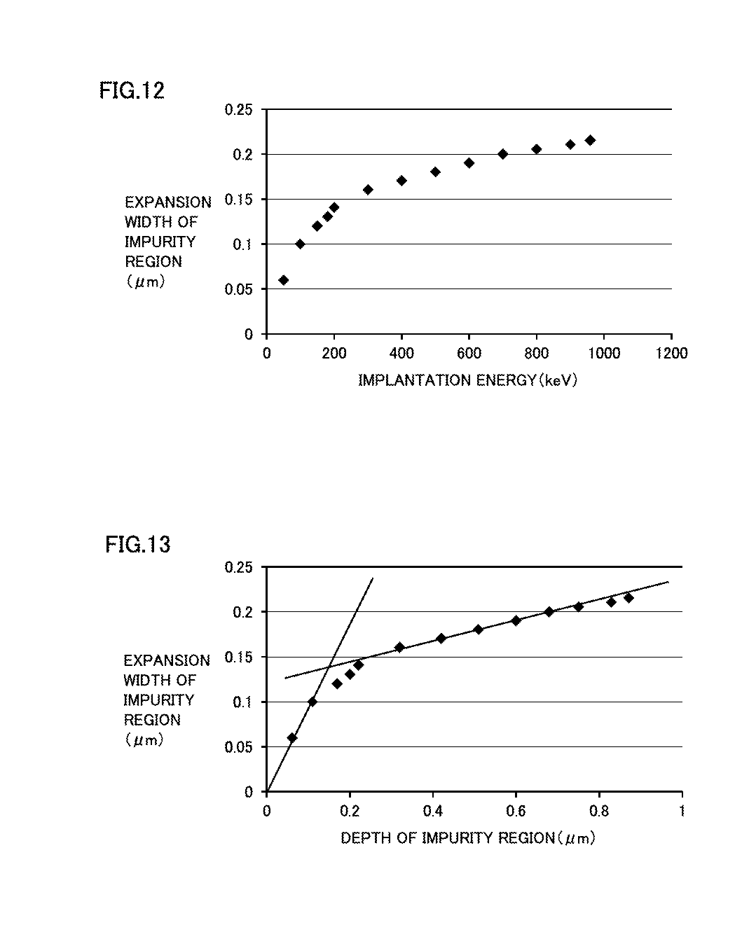

The calculation results are shown in FIG. 12 and FIG. 13. The horizontal axis of FIG. 12 represents the implantation energy (keV as a unit), whereas the vertical axis thereof represents the expansion width (μm as a unit) of the impurity region in the in-plane direction of the main surface of the silicon carbide substrate. The horizontal axis of FIG. 13 represents the depth (μm as a unit) of the impurity region from the main surface of the silicon carbide substrate, whereas the vertical axis thereof represents the expansion width (μm as a unit) in the in-plane direction of the main surface of the silicon carbide substrate. With reference to FIG. 12, it was confirmed that as the implantation energy for the impurity was increased, the impurity region tended to be expanded in the in-plane direction of the main surface. Moreover, with reference to FIG. 13 it was confirmed that as the impurity region was expanded in the in-plane direction of the main surface, the depth of the impurity region from the main surface tended to be deeper.

Moreover, when the adjustment film had a film thickness of 0.2 μm and the impurity had an implantation energy of 250 eV, the expansion width of the impurity region in the in-plane direction of the main surface was about 0.15 μm. Moreover, when the adjustment film had a film thickness of 0.2 μm and the impurity was implanted at an implantation energy of 50 eV, the expansion width of the impurity region in the in-plane direction of the main surface was about 0.05 μm.

From the result, it was confirmed that width L3 of p body region 13 between drift region 12 and n+ source region 14 in the main surface can be about 0.1 μm even when the thickness of adjustment film 2 is constant as long as the implantation energy for the impurity is about 250 eV in the step of forming p body region 13 and the implantation energy for the impurity is about 50 eV in the step of forming n+ source region 14.

Moreover, it was confirmed that the expansion width can be changed by changing the film thickness of the adjustment film while the implantation energy for the impurity is set to be constant. For example, the expansion width of the impurity region in the in-plane direction of the main surface when the implantation energy for the impurity was 230 eV and the thickness of the adjustment film was 0.55 μm was larger by 0.02 μm than that when the implantation energy for the impurity was 230 eV and the thickness of the adjustment film was 0.10 μm.

From the result, it was confirmed that by setting the film thickness of adjustment film 2 at about 0.55 μm in the step of forming p body region 13 and setting the film thickness of adjustment film 2 at about 0.10 μm in the step of forming n+ source region 14, width L3 of p body region 13 between drift region 12 and n+ source region 14 in the main surface can be about 0.02 μm even when the implantation energy for the impurity is constant.

Although the embodiments and examples of the present invention have been described as described above, the embodiments and examples can be modified in various manners. Moreover, the scope of the present invention is not limited to the embodiments and examples. The scope of the present invention is defined by the terms of the claims, and is intended to include any modifications within the scope and meaning equivalent to the terms of the claims.

### REFERENCE SIGNS LIST

1: mask film; 2: adjustment film, 3: opening end portion; 10: silicon carbide substrate; 10a: main surface; 11: n substrate; 12: drift region; 13: p body region; 14: n+ source region; 15: gate insulating film 16 source electrode, 17: gate electrode; 18: p+ region; 20: drain electrode; 100: silicon carbide semiconductor device.

1. A method for manufacturing a silicon carbide semiconductor device, comprising steps of:
preparing a silicon carbide substrate having a first surface and including a first impurity region having a first conductivity type;
forming an adjustment film and a mask film, said adjustment film covering at least a portion of said first surface, said mask film having an opening pattern through which said adjustment film is at least partially exposed;
forming a second impurity region having a second conductivity type in said first impurity region by implanting an impurity into said first surface through said adjustment film using said mask film as a mask;
removing at least a portion of said adjustment film; and
forming a third impurity region having the first conductivity type in said second impurity region by implanting an impurity into said first surface using said mask film as a mask after the step of removing at least the portion of said adjustment film.

2. The method for manufacturing the silicon carbide semiconductor device according to claim 1, wherein an implantation energy for the impurity in the step of forming said second impurity region is higher than an implantation energy for the impurity in the step of forming said third impurity region.

3. The method for manufacturing the silicon carbide semiconductor device according to claim 1, wherein in the step of removing, a film thickness of said adjustment film is decreased such that a portion of said adjustment film remains on said first surface.

4. The method for manufacturing the silicon carbide semiconductor device according to claim 1, wherein in the step of removing, said adjustment film on said first surface is removed to expose said first surface in said opening pattern of said mask film.

5. The method for manufacturing the silicon carbide semiconductor device according to claim 1, further comprising a step of forming an electrode to apply a voltage to a portion of said second impurity region between said first impurity region and said third impurity region.

6. The method for manufacturing the silicon carbide semiconductor device according to claim 1, wherein said adjustment film is made of a material selected from a group consisting of polycrystalline silicon, titanium, and silicon dioxide.

7. The method for manufacturing the silicon carbide semiconductor device according to claim 1, wherein in the step of forming said second impurity region, said adjustment film has a thickness of not less than 0.1 μm and not more than 1.0 μm, and in the step of forming said third impurity region, said adjustment film has a thickness of not less than 0.0 μm and not more than 0.95 μm.

8. The method for manufacturing the silicon carbide semiconductor device according to claim 1, wherein
said first conductivity type is n type and said second conductivity type is p type,
in the step of forming said second impurity region, aluminum or boron is implanted as the impurity, and
in the step of forming said third impurity region, phosphorus is implanted as the impurity.

9. The method for manufacturing the silicon carbide semiconductor device according to claim 1, wherein an implantation energy for the impurity in the step of forming said second impurity region is not less than 10 keV and not more than 1000 keV, and an implantation energy for the impurity in the step of forming said third impurity region is not less than 10 keV and not more than 500 keV.

10. A silicon carbide semiconductor device comprising a silicon carbide substrate having a first surface,
said silicon carbide substrate including
a first impurity region formed in said first surface and having a first conductivity type, and
a third impurity region having said first conductivity type and facing said first impurity region with a second impurity region being interposed therebetween in said first surface, said second impurity region having a second conductivity type,
said second impurity region between said first impurity region and said third impurity region in said first surface having a width of not less than 0.01 μd not more than 0.15 μm.
